(19) United States
(12) Patent Application Publication
(10) Pub. No.: US 2026/0246433 A1
(43) Pub. Date: Aug. 20, 2026

(54) REVERSED FEEDBACK AMPLIFIER AND CASCADED WIDEBAND HIGH-GAIN AMPLIFIER CIRCUITS

(71) Applicant: The Regents of the University of California, Oakland, CA (US)

(72) Inventors: Saleh Hassanzadehyamchi, Davis, CA (US); Omeed Momeni, Davis, CA (US); Ali M. Niknejad, Davis, CA (US); Amirreza Alizadeh, Davis, CA (US)

(21) Appl. No.: 19/542,190

(22) Filed: Feb. 17, 2026

Related U.S. Application Data
(60) Provisional application No. 63/760,763, filed on Feb. 20, 2025.

(51) Int. Cl. H03F 3/193; H03F 3/195

(52) U.S. Cl. CPC H03F 3/193; H03F 3/195; H03F 2200/451

(57) ABSTRACT

A reversed feedback amplifier includes a MOSFET having a drain input terminal connected to an amplifier input port and a gate output terminal connected to an amplifier output port. A passive shunt admittance is between the amplifier input and output terminals. A series passive impedance is in series with a source common terminal of the MOSFET. A pre-embedding capacitive admittance is between the drain input terminal and the source common terminal of the MOSFET. The passive shunt admittance and series passive impedance are selected to provide max gain operation of the MOSFET, and the pre-embedding capacitive admittance is selected to be absorbed into drain-source parasitic capacitance of the MOSFET, and to compensate passive losses of the passive shunt admittance and the series passive impedance.

### PRIORITY CLAIM AND REFERENCE TO RELATED APPLICATION

The application claims priority under 35 U.S.C. § 119 and all applicable statutes and treaties from prior U.S. provisional application Ser. No. 63/760,763, which was filed Feb. 20, 2025. All applications mentioned in this paragraph are incorporated by reference.

### FEDERALLY SPONSORED RESEARCH AND DEVELOPMENT

This invention was made with government support under grant no. 1932821 awarded by the National Science Foundation. The government has certain rights in the invention.

### FIELD

A field of the invention is amplification of mm-wave signals. Example applications that benefit from use of amplifiers and amplifier circuits of the invention include wireless communications, data center communication circuits, high-resolution imaging, advanced radars, and other applications that demand consistent, high-power, broadband operation in mm-wave frequency bands.

### BACKGROUND

Sub-THz circuit design in CMOS is challenging. At G-band, the dissipative loss associated with device internal parasitics and passive elements dominates the device performance. Consequently, the maximum available gain (Gₘₐₓ) of the transistors declines dramatically, particularly over halfƒₘₐₓ. Cascading multiple stages can obtain a higher gain, but merely implementing a cascade increases the chip area and DC power consumption. Gₘₐₓ techniques used in feedback amplifiers (FBAs) have been realized only over a narrow bandwidth (≤12%).

Stagger tuning employing multiple cascaded stages tuned at different center frequencies can be used to expand bandwidth. Stagger-tuned amplifiers (STAs) often suffer from poor input or output return losses, because each constituting stage is narrowband and exhibits poor matching responses (i.e., S₁₁ and S₂₂) at the center frequency of other stages.

FIGS. 1A and 1B respectively show two common structures of feedback amplifiers 100 and 102 that can potentially lead the A2P (active two-port network) 104 to Gₘₐₓ operation point. These common active two-port network feedback amplifiers are disclosed, for example the following publications. W. Park, D. R. Utomo, B. H. Lam, S. G. Lee and J. P. Hong, “A 230-260-GHz Wideband and High-Gain Amplifier in 65 nm CMOS Based on Dual-Peak G_max-Core,” in IEEE Journal of Solid-State Circuits, vol. 54, no. 6, pp. 1613-1623 Jun. 2019. W. Park, D. R. Utomo, B. Yun, H. U. Mahmood, J. P. Hong, and S. G. Lee, “Design of high-gain sub-THz regenerative amplifiers based on double-G_max gain boosting technique,” IEEE J. Solid-State Circuits, vol. 56, no. 11, pp. 3388-3398 Nov. 2021. H. Bameri and O. Momeni, “A 200-GHz Power Amplifier with a Wideband Balanced Slot Power Combiner and 9.4-dBm P sat in 65-nm CMOS: Embedded Power Amplification,” in IEEE Journal of Solid-State Circuits, vol. 56, no. 11, pp. 3318-3330 Nov. 2021. In FIG. 1A, the Gₘₐₓ-core is realized by adding two reactive elements to A2P 104 (parallel embedding with admittance of jB_{P1} and series embedding with impedance of jX_{S1}), and FIG. 1B shows the Gₘₐₓ-core with three reactive elements (pre-embeddings with impedances of jX_{P1} and jX_{P2}, and then, parallel embedding with admittance of jB_{P1}). The series embedding in FIG. 1A is capacitive and thus, a λ/4TL is required to bias the source of the transistor 104, which adds complexity and additional loss to the structure.

The idea of using a transistor in the reversed direction with passive feedback was proposed in the following publications. J. Buckwalter and J. Kim, “A 26-dB gain, 100 GHz cascaded constructive wave amplifier in a Si/SiGe technology,” in IEEE Int. Solid-State Circuits Conf. Dig., Feb. 8-12, 2009, pp. 488-489; J. F. Buckwalter and J. Kim, “Cascaded constructive wave amplification,” IEEE Trans. Microw. Theory Techn., vol. 58, no. 3, pp. 506-517, March 2010. The structure is named “constructive-wave amplifier.” The publications showed that signal amplification can be achieved from the constructive wave structure. This topology in the publications only includes shunt embedding using a transmission line (TL). The structure is assumed to be terminated to 500 in the input and output ports, and thus, does not include input or output matching networks (IMNs & OMNs). Making the assumption of a termination to 500 in the input and output ports deviates the amplifier from optimum condition. The loading effect of transistor parasitics on the TL is neglected. Only a single optimum design point is determined in which the TL has a length of λ/4 and characteristic impedance of 500 at the operation frequency. The topology of the structure and its analysis include several limitations that cause sub-optimal operation. The limitations include 1) the structure is not capable of Gₘₐₓ operation. 2) it has only one design point which is suboptimal. 3) the structure does not have the capability of overcoming passive losses after layout. The structure also includes an emitter-follower stage to decrease the loading and improve stability, but this is at the cost of increased DC power consumption.

### SUMMARY

A reversed feedback amplifier according to an embodiment of the invention includes a MOSFET comprising a drain input terminal connected to an amplifier input port and a gate output terminal connected to an amplifier output port. A passive shunt admittance is between the amplifier input and output terminals. A series passive impedance is in series with a source common terminal of the MOSFET. A pre-embedding capacitive admittance is between the drain input terminal and the source common terminal of the MOSFET. The passive shunt admittance and series passive impedance are selected to provide max gain operation of the MOSFET. The pre-embedding capacitive admittance is selected to be absorbed into drain-source parasitic capacitance of the MOSFET, and to compensate passive losses of the passive shunt admittance and the series passive impedance.

A cascaded amplifier according to an embodiment of the invention includes a reversed feedback amplifier tuned to a first frequency and a second feedback amplifier tuned to a second frequency that is different than the first frequency. A plurality of reversed feedback amplifier cells can be used, and no matching networks are required between the plurality of reversed feedback amplifier cells.

### BRIEF DESCRIPTION OF THE DRAWINGS

FIGS. 1A (Prior Art) and 1B (Prior Art) are schematic diagrams of two common structures of feedback amplifiers.

FIG. 2 is a schematic diagram of a reversed feedback amplifier (RFBA) according to an embodiment of the invention.

FIG. 3 represents reversed feedback amplifier of FIG. 2 with a physical layout in accordance with a preferred embodiment.

FIG. 4 is a plot of maximum available gain versus frequency for the reversed feedback amplifier of FIG. 2 with pre-embedding capacitance adjusted as a design variable.

FIGS. 5A and 5B respectively show equivalent noise models of (a) a FET two port network (A2P) alone and the (b) series- and parallel-embedded A2P in the RFBA of FIG. 2.

FIG. 6A is a plot of minimum noise contours of the RFBA of FIG. 2.

FIG. 6B is a plot of minimum noise contours varying from 2 to 9 dB of the RFBA of FIG. 2.

FIG. 6C is a plot of minimum noise contours for an amplifier with multiple FIG. 2 RFBA stages.

FIG. 7 illustrates the mismatch loss due to elimination of matching networks between amp cells in an amplifier having multiple FIG. 2 RFBA stages.

FIG. 8 shows an equivalent circuit of an RFBA 200 of FIG. 2 terminated to iterative impedances.

FIG. 9 depicts the simplified model of RFBA cells of FIG. 2 in a cascaded configuration in which VCCSs are replaced with their equivalent admittances

FIG. 10 shows a final equivalent circuit of a cell in a cascaded configuration of RFBA cells of FIG. 2.

FIGS. 11A-11C respectively plot characteristic transmission line impedance, transmission line propagation factor and power gain for an example RFBA cells in accordance with FIG. 2.

FIG. 12 is a schematic diagram of a transmission line loaded with shunt negative resistors.

FIG. 13 plots transducer power gain versus frequency of a shunt transmission line with different values of negative resistance.

FIG. 14 is an equivalent circuit of the FIG. 2 RFBA cell terminated to iterative impedances used for reverse gain analysis.

FIGS. 15A-15C respectively plot characteristic transmission line impedance, transmission line propagation factor and power gain for an example RFBA cells in accordance with FIG. 2.

FIG. 16 is a gain and stability plot of a cascaded CFBA and RFBA amplifier of an embodiment of the invention.

FIGS. 17A and 17B show cascaded amplifiers according to embodiments of the invention.

FIG. 18A is a plot of bandwidth and gain bandwidth product versus the number of RFBA stages for cascaded amplifiers of embodiments of the invention in accordance with FIGS. 17A and 17B.

FIG. 18B is a plot gain versus frequency for cascaded amplifiers of embodiments of the invention in accordance with FIGS. 17A and 17B.

### DETAILED DESCRIPTION OF THE PREFERRED EMBODIMENTS

A reversed feedback amplifier (RFBA) cell according to an embodiment discussed herein achieves gain boosting by using pre-embedding and embedding elements together. The RFBA can behave like a transmission line periodically loaded by negative resistors and therefore is internally matched, eliminating the need for interstage-matching networks that introduce dissipative loss and limit the bandwidth. Further bandwidth extension can be achieved by cascading a common non-reversed feedback amplifier (CFBA) and the RFBA, realizing a high gain over a broad bandwidth.

A reversed feedback amplifier according to an embodiment of the invention includes a MOSFET comprising a drain input terminal connected to an amplifier input port and a gate output terminal connected to an amplifier output port. A passive shunt admittance is between the amplifier input and output terminals. A series passive impedance is in series with a source common terminal of the MOSFET. A pre-embedding capacitive admittance is between the drain input terminal and the source common terminal of the MOSFET. The passive shunt admittance and series passive impedance are selected to provide max gain operation of the MOSFET. The pre-embedding capacitive admittance is selected to be absorbed into drain-source parasitic capacitance of the MOSFET, and to compensate passive losses of the passive shunt admittance and the series passive impedance.

A cascaded amplifier according to an embodiment of the invention includes a reversed feedback amplifier tuned to a first frequency and a second feedback amplifier tuned to a second frequency that is different than the first frequency. A plurality of reversed feedback amplifier cells can be used, and no matching networks are required between the plurality of reversed feedback amplifier cells. Cascaded amplifiers of the invention can be tuned to provide gain over a wide bandwidth.

Two example amplifier prototypes in accordance with embodiments disclosed herein were designed and fabricated to measure and test for gain and bandwidth performance. The example fabrications were in a 45—nm CMOS SOI process with ƒₘₐₓ of 310 GHz. The first example amplifier achieved an average gain of 12 dB over 156193.8 GHz, whereas the second example amplifier achieved an average gain of 17 dB at 157.4-194.2 GHz. Both example designs provided gain up to ≈0.56ƒₘₐₓ while achieving 6.2~13 dB noise-figure and 6 dBm peak output power.

Preferred embodiments of the invention will now be discussed with respect to experiments and drawings. Broader aspects of the invention will be understood by artisans in view of the general knowledge in the art and the description of the experiments that follows.

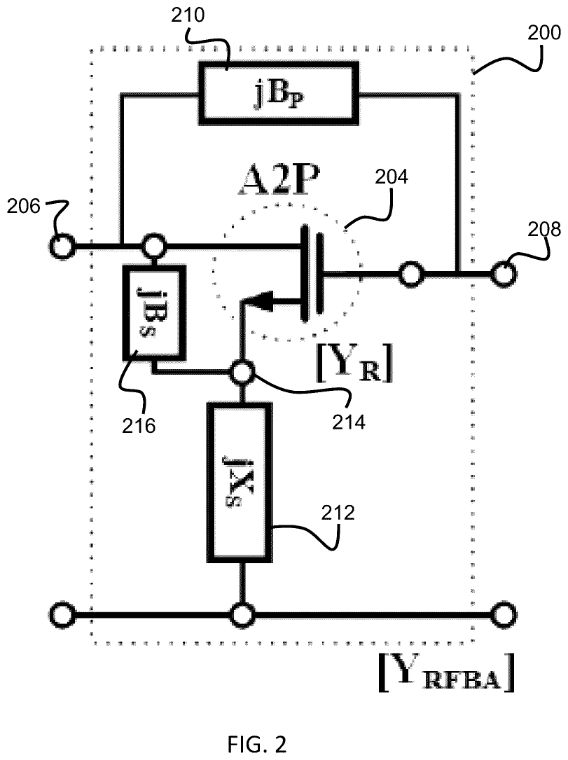

FIG. 2 shows a reversed feedback amplifier 200 according to an embodiment of the invention. A MOSFET (A2P) serves as an active two-port network 204 and is connected in the reversed direction, with its drain and gate connected to amplifier input 206 and output 208 ports, respectively. The FET A2P is embedded simultaneously by parallel and series passive elements. A passive admittance 210 of jB_{P} between the input 206 and output 208 terminals of the FET A2P 204 provides shunt-embedding, and the series embedding is realized by adding a passive impedance 212 of jX_{S} in series with a common terminal 214 of the FET A2P 204. Embedding, as used herein, refers to insertion of a passive device. The parallel 210 and series 212 embedding respectively introduce negative and positive feedback to the amplifier 200.

A pre-embedding capacitive admittance 216 of jB_{S} is between the drain and source nodes of A2P 204. This pre-embedding capacitive admittance 216 can be absorbed into the drain-source parasitic capacitance of the A2P 204. Artisans will appreciate that the series embedding 212 makes the structure capable of Gₘₐₓ operation, and that the pre-embedding capacitive admittance 216 (jB_{S}) helps to compensate passive losses. Artisans will also appreciate that mapping the reversed feedback amplifier 200 into the gain plane can provide design points and can be used to determine optimum load and source impedances. Pre-embedding, as used herein, also means that the capacitive admittance (jB_{S}) is absorbed as part of the A2P 204, and does not introduce any feedback from input to output.

The FIG. 2 RFBA arrangement of pre-embedding and series embedding removes the need for a buffer stage that is used in the “constructive-wave amplifier” type of reversed feedback amplifier that is discussed in the background above with respect to the publications of Buckwalter et al.

### Analysis of the FIG. 2 Reversed Feedback Amplifier 200

### A. Maximum Achievable Power Gain (Gₘₐₓ) Operation Point

The maximum available gain (Gₘₐ) of the FET A2P can be boosted to directionally independent gain U or Gₘₐₓ with the appropriate design of the load and source impedances. Because U is independent from the direction of device, Gₘₐₓ should be obtainable from RFBA shown in FIG. 2 as well. A known gain-plane approach of provides a good graphical representation in the study of the stability and the power gain of the FIG. 2 Reversed Feedback Amplifier (RFBA) 200. With the definition of maximum stable gain (MSG) as A=Y₂₁/Y₁₂, the loci of constant gain and Kstability factor contours can be located in the gain-plane with axes x= [symbol] (1/A) and ℑ=3 (1/A). Using the admittance parameters of the RFBA 200 and assuming |−Y₁₂/ΔY|=|Z₁₂|<<|X_{S}+B_{P}ΔZ_{S}|, the coordinate of the RFBA 200 in the gain-plane is obtained from standard gain plane analysis equations:

$$\frac{1}{{A}_{RFBA}} = 1 + j \frac{\frac{{Y}_{21}}{Δ Y}}{{X}_{S} + {B}_{P} \cdot Δ {Z}_{S}} \qquad ( 1 )$$

The embedded FET 204 achieves Gₘₐₓ in the coordinate of the point

$$( - \frac{1}{2 U - 1 + 2 \sqrt{U ( U - 1 )}} , 0 )$$

of the plane. Thus, for Gₘₐₓ operation, the embedding networks of the RFBA 200 should be designed to satisfy the conditions:

$${}^{} 𝔍 ( \frac{\frac{{Y}_{21}}{Δ Y}}{{X}_{S} + {B}_{P} \cdot Δ {Z}_{S}} ) = 1 + \frac{1}{2 U - 1 + 2 \sqrt{U ( U - 1 )}} \qquad ( 2 a )$$

$$ℜ ( \frac{\frac{{Y}_{21}}{Δ Y}}{{X}_{S} + {B}_{P} \cdot Δ {Z}_{S}} ) = 0$$

In equation (1), the real part coordinates to the x-axis in the gain plane, and the imaginary part coordinated to the y-axis. Equation (1) can be considered as the amp-cell-coordination in the gain plane. Equation (2) is the resulting solution from equation (1) for Gₘₐₓ operation. To verify (2), a 13.6—μm transistor in a 45—nm CMOS SOI process is used as A2P, and the embedding elements (X_{S} and B_{P}) as well as their corresponding physical implementation at 180 GHz are illustrated in TABLE I. The pre-embedding jB_{S} is implemented by C_{ds}, ext. For each variation of C_{ds}, ext, solving (2) leads to two Gₘₐₓ operation points, and both cases can be realized by transmission lines (TLs) for X_{S} and B_{P} implementation. The associated calculated characteristic impedances (Z_{S} and Z_{P}) and electrical length (l_{S} and l_{P}) of the TLs show that that the first solution provides a practical solution, since the 105ΩTL in the second case is not easily implemented. Furthermore, l_{S} and l_{P} tend to decrease with higher C_{ds}, ext, thereby introducing lower TL losses, which is favorable at mm-wave frequencies

TABLE I
Theoretical embedding calculation to achieve Gₘₐₓ For
a 13.6- μm TRANSISTOR AT 180 GHz IN 45 - nm SOI.

| | | | | Z_{S}(Ω), | Z_{P}(Ω), |
|---|---|---|---|---|---|
| B_{S}(mΩ) | C_{ds, ext} (fF) | X_{S}(Ω) | B_{P}(m [symbol] ) | l_{S}(deg). | l_{P}(deg). |
| ∞ | 0 | 69.7 | −17.15 | 50, 54.3 | 65, 63.8 |
| ∞ | 0 | 606.7 | −9.79 | 50, 85.3 | 105, 76.6 |
| −2.26 | 2 | 68.2 | −17.7 | 50, 53.7 | 65, 60.4 |
| −2.26 | 2 | 336.1 | −10.92 | 50, 81.5 | 105, 60.7 |
| −4.52 | 4 | 65.3 | −18.4 | 50, 52.7 | 65, 56.6 |
| −4.52 | 4 | 251.8 | −11.86 | 50, 78.8 | 105, 53.4 |

Table I values were taken with Bias point: J=300 μA/μm, V_{GS}=V_{DS}=0.6 V. Channel length: 40-nm.

### B. Gain-Boosting Technique Through Device Pre-Embedding

In practice, the loss introduced by embedding elements 210 and 212 limits the performance of the of the FIG. 2 RFBA 200. Therefore, the pre-embedding 216 is employed as an alternative gain-boosting technique to compensate for the losses of the embeddings 210 and 212 and is implemented with the additional C_{ds}, ext placed in between the drain and source nodes of the FET A2P 204.

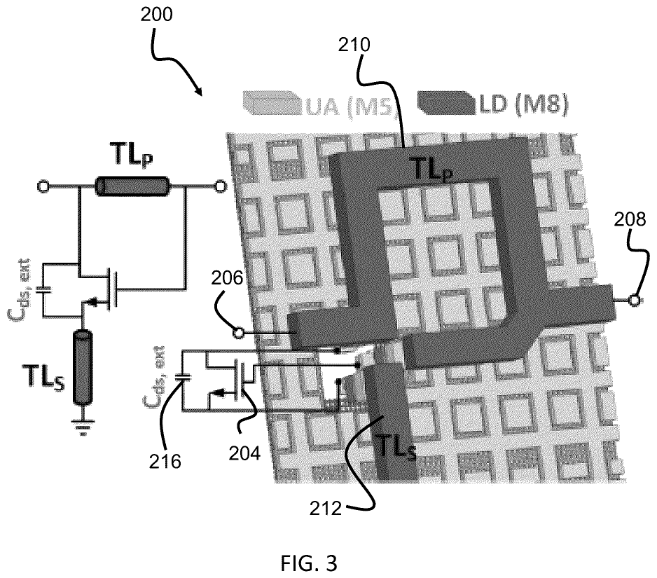

FIG. 3 represents an RFBA 200 of FIG. 2 with physical layout in accordance with a preferred embodiment in which C_{ds}, ext is taken as a design variable. The embedding elements 210 and 212 are transmission lines TLₚ and TLₛ. Note that TL_{S} is only partially shown, so the relative lengths of the transmission lines are not shown in the FIG. 3

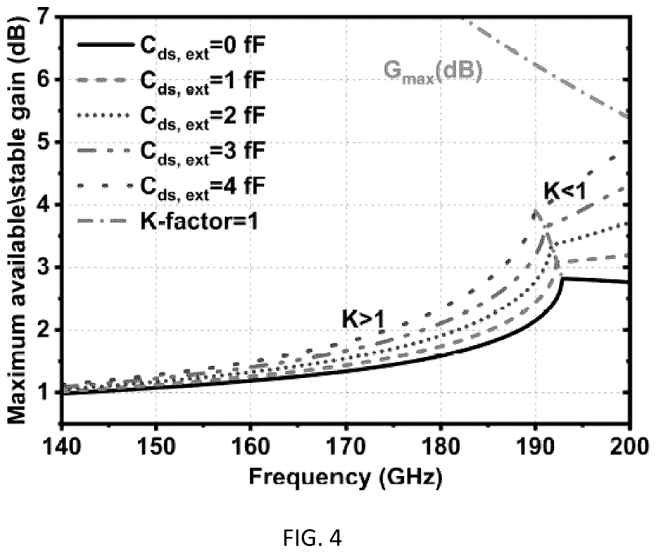

FIG. 4 plots C_{ds}, ext variation effect on Gₘₐ \ Gₘₛ of an RFBA 200 of FIG. 2. The FET size is 13.6—μm with 40—nm channel length. Bias point: J=300 μA/μm, V_{GS}=V_{DS}=0.6 V. For a given length of TLₚ and TLₛ simulated using 3D EMsimulator, Gₘₐ of the RFBA is plotted in FIG. 4, and the results illustrates that Gₘₐ increases with higher C_{ds}, ext at 190 GHZ, while the amplifier is unconditionally stable below 190 GHz for all C_{ds, ext} values. The pre-embedding C_{ds}, ext moves the coordinate of the RFBA 200 to the left in the gain plain, thereby leading to higher gains close to Gₘₐₓ operation point and overcoming the loss.

### C. Noise Figures

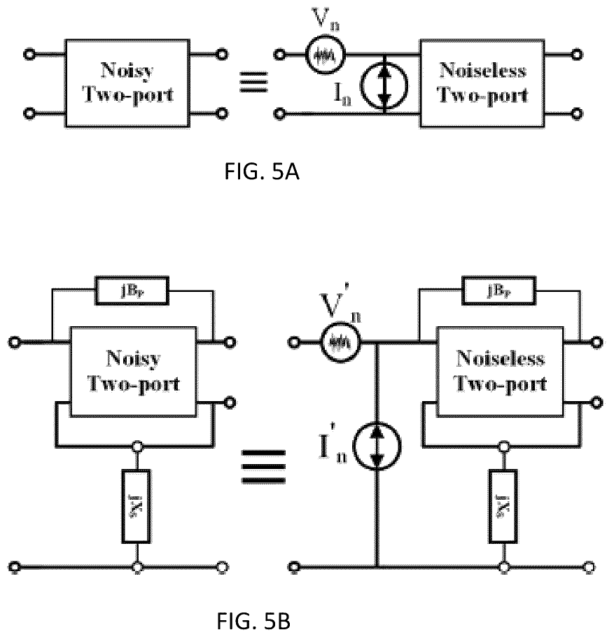

FIGS. 5A and 5B show the equivalent noise model of (a) FET A2P 204 alone and (b) series- and parallel-embedded A2P in the RFBA 200 of FIG. 2. A two-port network with internal noise sources can be represented with a noise-free two-port preceded by two equivalent noise sources Vₙ and Iₙ (FIG. 5A). The noise figure of the FET A2P 204 is expressed in terms of four noise parameters: the equivalent noise resistance Rₙ, uncorrelated equivalent conductance Gᵤ, and correlation admittance Y_{c}. FIG. 5B shows the embedded FET A2P 204 with its equivalent input-referred sources

$${V}_{n}^{′} and {I}_{n}^{′} .$$

The pre-embedding element 216 jB_{S} is absorbed into the y-parameters of A2P 204 and does not change the minimum noise figure.

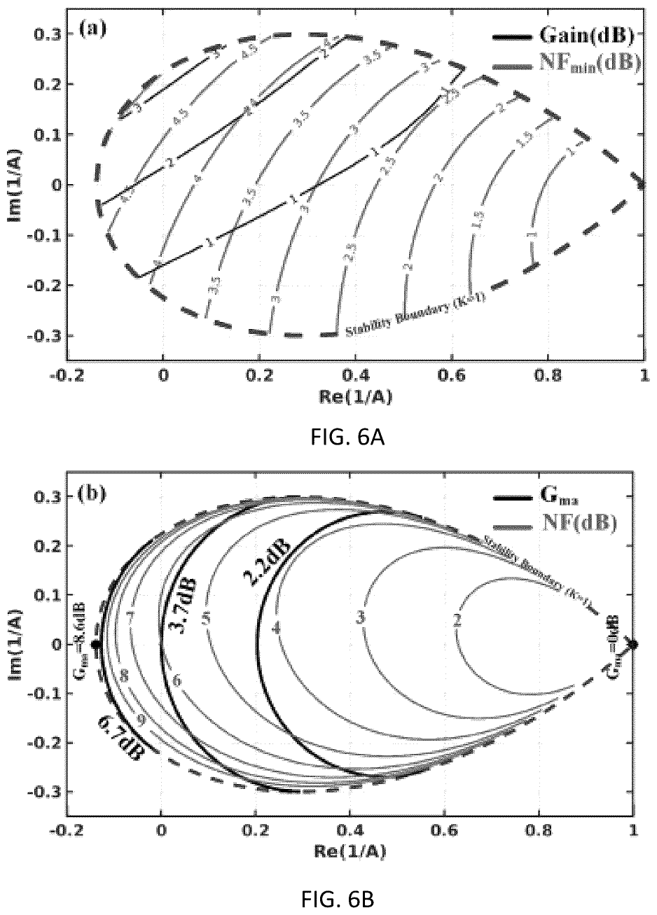

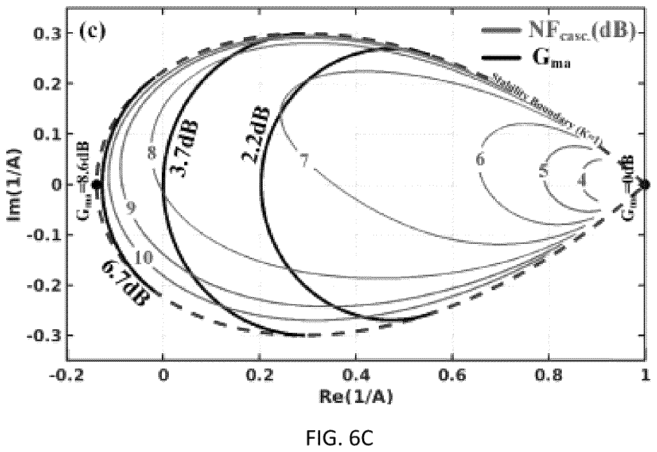

To study the effect of series- and parallel embeddings on the noise performance of RFBA, two cases are considered:
1) The RFBA 200 can be configured for the minimum noise matching. The constant NF in contours are plotted in FIG. 6A. The optimum impedances for noise matching is also derived and the associated gain contours is added to the plot. It can be seen from the graph that the RFBA can achieve 3—dB maximum gain with a noise figure slightly higher than 4.5 dB, while operating close to the stability boundary.
2) The RFBA is aimed for the best gain performance, and thus, designed for maximum available gain. The constant NF contours are graphed in FIG. 6B varying from 2 to 9 dB. It can be seen from the graph that the upper horizontal half (ℑ(1/A)>0) obtains a better noise figure.
   Comparing the two cases, the former does not show a superior simultaneous noise and gain performance over the latter, and its gain is limited to 3 dB. The latter is preferred for an actual design with a gain range of 8.6 dB. Including pre-embedding leads to similar results to FIG. 6. Finally, the noise figure of a multi-stage RFBA its contours are plotted in FIG. 6C.

The reversed feedback amplifier 200 of FIG. 2 can be cascaded to provide high gain and wide bandwidth amplification. Several amplifying cells (amp-cells) can be cascaded to attain a desired gain for mm-wave applications. In conventional applications, an interstage matching network (ISMN) is required in between the cells to terminate the amp-cell to the desirable load and source impedances. However, ISMNs are lossy (1-2 dB at G-band) and often limit the bandwidth. To avoid such issues, we determine performance of cascaded amp-cells in a preferred embodiment while no ISMN is included, and its performance is compared to conjugate-matched cascaded amp-cells.

### Iterative Impedance

For each point in the gain-plane, the associated shunt embedding TLₚ shown in FIG. 3 can be implemented over a range by adjusting its characteristic impedance (Zₚ). TLₛ are assumed to be lossless. To find the best G_{IT}, hence, Zₚ is swept from 40 to 90Ω, and then, the maximum G_{IT} is selected for each point in the gain-plane.

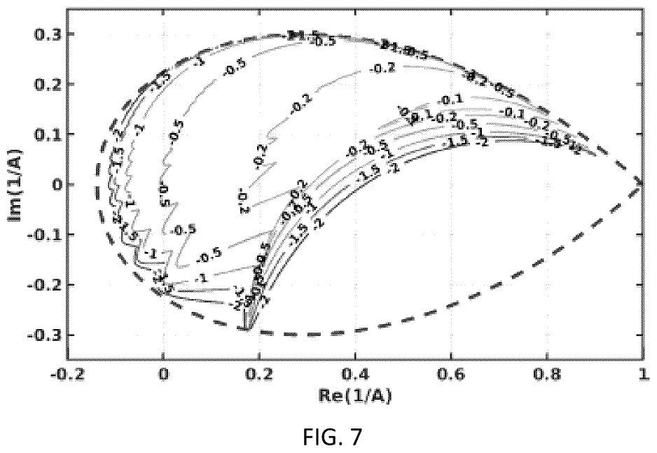

FIG. 7 illustrates the mismatch loss (G_{IT,dB}-G_{ma,dB}) due to elimination of ISMNs in between the amp-cells. Cascading multiple RFBAs with no ISMNs is beneficial in terms of gain, BW, and die area.
1) Because ISMNs presents 1-2 dB dissipative loss and often limit the BW at G-band, any design point chosen inside the −2 dB contour in FIG. 7 will result in the same or better gain performance compared to Gₘₐ as well as higher BW for two or more cascaded amp-cells. Later, it will be shown that the loaded TLₚ is equivalent to an artificial transmission line, and hence, all cells are intrinsically matched.
2) The ISMN exclusion from the design of the cascaded RFBA amplifiers leads to an area efficient amplifier.

### Analytical Behavior of Cascaded RFBAs

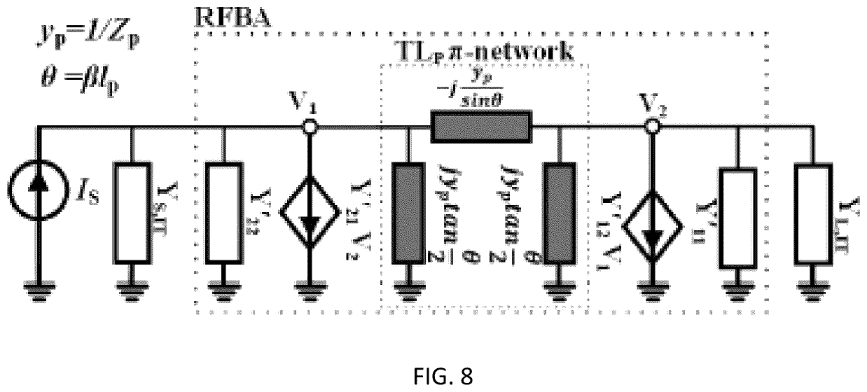

FIG. 8 shows the equivalent circuit of an RFBA 200 of FIG. 2 terminated to iterative impedances, which is used to analyze the RFBA transducer gain. TLₚ is substituted with its equivalent π network where yₚ=1/Zₚ. The Y-parameters of the network loading the line represents the reversed device with series embedding and pre-embedding with B_{S}=C_{ds, ext}ω and X_{S}=Z_{S} tan θ (θ=βlₚ in which β=2π/λ is the wavenumber). From KCL analysis, both voltage-controlled current sources (VCCSs)

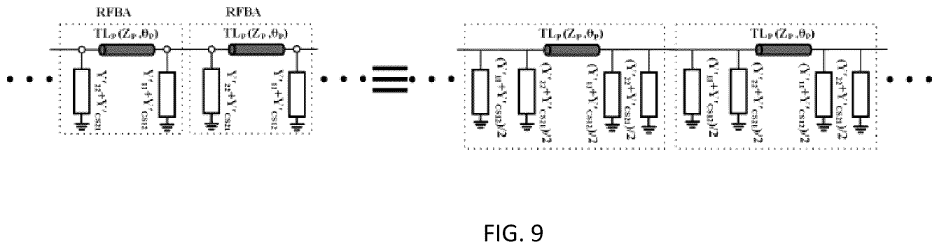

FIG. 9 depicts the simplified model of RFBA cells in a cascaded configuration in which VCCSs are replaced with their equivalent admittances. The model presented herein is applicable only to the forward-propagating signal. Thanks to ISMN exclusion, shunt loadings of the TLₚ can be shared between the cells.

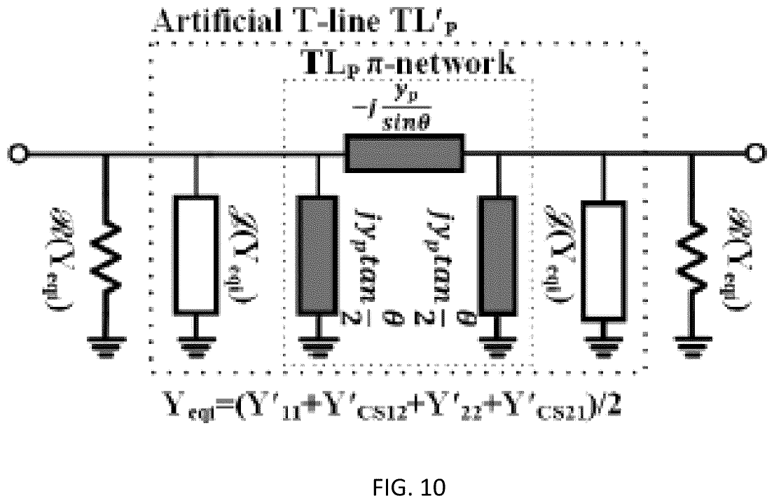

FIG. 10 shows final equivalent circuit of a cell in a cascaded configuration of RFBAs. The shunt loading Y_{eqi} is separated into imaginary and real parts. TLₚ symmetrically shunt-loaded with 3 (Y_{eqi}) creates a new π-network, and is equivalent to an artificial TL.

Cascaded RFBAs 200 of FIG. 2 can be modeled as a cascade of artificial transmission lines

$$( {TL}_{P}^{′} )$$

symmetrically shunt-loaded with frequency-dependent resistors ( [symbol] (Y_{eqi}). Ideally, without the shunt resistive loading, the gain of a cascaded

$${TL}_{P}^{′}$$

is equal to one in its passband, and both attenuation and amplification can be obtained from the structure given [symbol] (Y_{eqi}) is positive or negative, respectively. Since power amplification is targeted in the forward direction, the shunt loading of the

$${TL}_{P}^{′}$$

is a negative resistor, wine a positive resistor is favorable in the reverse direction to guarantee stability.

The behavior of the preferred RFBA 200 without the pre-embedding capacitance was considered with a particular example fabrication using a 13.6 μm NMOS transistor in 45—nm SOI process biased at J=300 μA/μm, V_{GS}=V_{DS}=0.6 V is chosen and embedded with 50—Ω transmission lines (θ_{P}=59.3° and θ_{S}=65.4° at 180 GHZ).

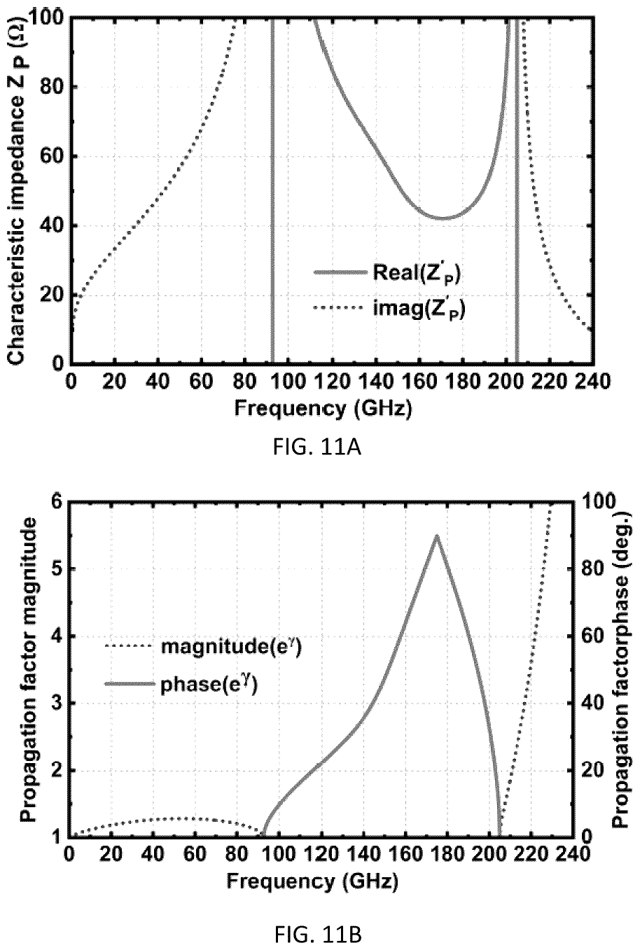

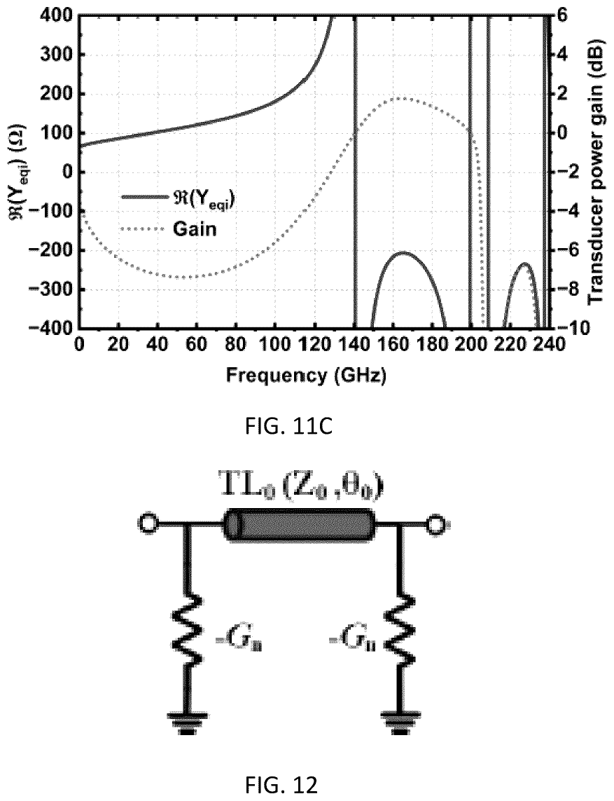

FIGS. 11A-11C plot characteristic impedance, propagation factor and power gain for a cascaded configuration of RFBA cells of FIG. 2. FIG. 11A shows Characteristic impedance

$$( {Z}_{P}^{′} )$$

of

$${TL}_{P}^{′} ,$$

FIG. 11B shows factor (e^{γ}) of

$${TL}_{P}^{′} ,$$

and (C) [symbol] (Y_{eqi}) for an example 13.6—μm NMOS transistor in 45 nm SOI embedded with 50—Ω transmission lines (θ_{P}=57.8° and θ_{S}=65.4° at 175 GHz). Bias point: J=300 μA/μm, V_{GS}=V_{DS}=0.6 V. The equivalent artificial line

$${TL}_{P}^{′}$$

is a band-pass filter with resonance frequencies of 85—and 202—GHz. It can also be seen from FIG. 11 that:
1) For 85 GHz <f<202 GHz (pass-band):

$${Z}_{P}^{′}$$

and γ are real and imaginary, respectively. The phase of e^{γ} increases from zero at 85 GHz and reaches 90° at 175 GHz. Then, it starts decreasing and reaches zero again at 202 GHz. In the pass-band, |e^{γ}|=1.
2) For f<85 GHZ and f>202 GHZ (stop-band):

$${Z}_{P}^{′}$$

is imaginary and e^{γ} becomes real and higher than one, showing a rising attenuation. Hence, signal amplification can only occur in the pass-band of

$${TL}_{P}^{′}$$

and only if it is loaded with negative resistor. Graphed in FIG. 11C, [symbol] (Y_{eqi}) has four resonance frequencies-140-,197-,207-, and 239-GHz, and it becomes negative at 140 GHZ <f<197 GHZ and 207 GHZ <f<239 GHZ. The latter is out of scope due to its occurrence in the stop-band, while the former determines the amplification range that can be achieved from the structure in this specific example. At resonance frequencies of 140—and 197—GHz, the transducer power gain obtained from cascaded RFBAs is 0 dB and reaches the maximum of 1.8 dB in the pass band (FIG. 11C). Also, small variation of

$${Z}_{P}^{′}$$

in the amplification range provides reasonable input and output matching conditions for the full cascaded amplifier.

### Center Frequency (f_{c})

FIG. 12 shows a TL loaded with shunt negative resistors. The simplified model of FIG. 12 can be utilized to find the center frequency of cascaded RFBAs. TL₀ has a constant characteristic impedance with the propagation factor of e^{-jθ} and is loaded with shunt constant negative resistors (Gₙ). Assuming the structure terminated to its corresponding iterative impedances and Y₀=1/Z., G_{IT} is derived as

$${G}_{IT} = - {Z}_{0}^{2} {sin}^{2} θ \times$$

At center frequency, G_{IT} must reach its peak value.

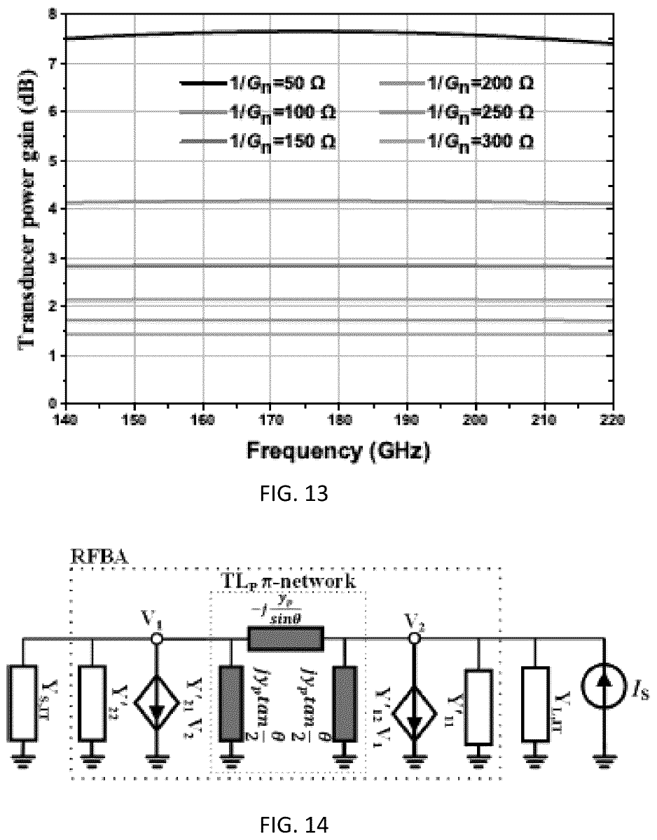

FIG. 13 graphs G_{IT} for a 50ΩTL with 0.5π length at 175 GHZ, and shunt-loaded with negative resistors ranging from 50 to 300Ω. The structure has flat responses over a wide BW, and achieves higher gain with higher Gₙ. The graph also shows that ƒ_{c} remains unaffected by the value of Gₙ, and is at 175 GHz, as the line corresponds to a quarter wavelength at that frequency. Referring back to the propagation factor plotted in FIG. 11B,

$${TL}_{P}^{′}$$

is also centered at 175 GHz with an electrical length of π/2. Nevertheless, since [symbol] (Y_{eqi}) and

$${Z}_{P}^{′}$$

are frequency-dependent, and also, [symbol] (Y_{eqi}) peak has a slight shift from 175 GHz, the simulated ƒ_{c} deviates from 175 GHz about 3 GHz.

### Bandwidth (BW)

In the cascaded configuration of RFBAs, the variation of the propagation factor causes gain change over the frequency (FIG. 11C). The total gain of the cascaded RFBA cells is the multiplication of the gain of the each individual cell (G_{IT}). To find 3-dB BW of n-cascaded cells, first, the power gain of the single stage (G_{IT@fx}) at the 3-dB frequency (ƒₖ) of n-stage amplifier is determined from

$$20 {log ( \frac{{G}_{IT , max}}{{G}_{IT @ fk}} )}^{n} = 3$$

Then, the calculated value of G_{IT@fk} is mapped into FIG. 11(C) and the 3—dB BW corresponding frequencies are extracted. For instance, for n=9, BW is 27.4 GHZ, from 153 to 179 GHz, and it is in close agreement with the simulation results (149174 GHZ).

### Reverse Gain

FIG. 14 is an equivalent circuit of the FIG. 2 RFBA cell 200 terminated to iterative impedances used for reverse gain analysis. Similar to forward gain modeling, here the VCCSs are replaced by their equivalent admittances.

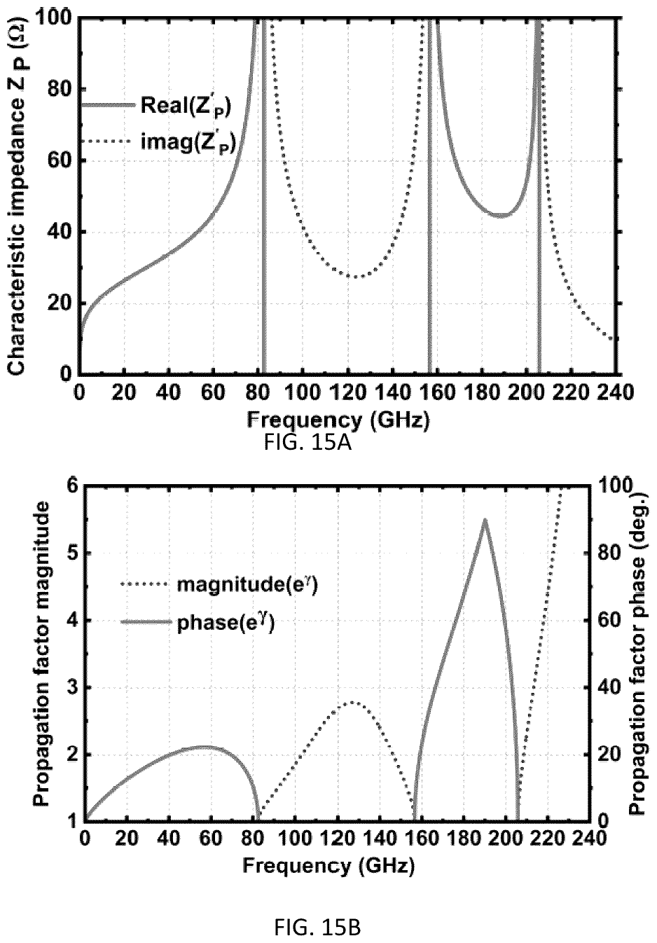

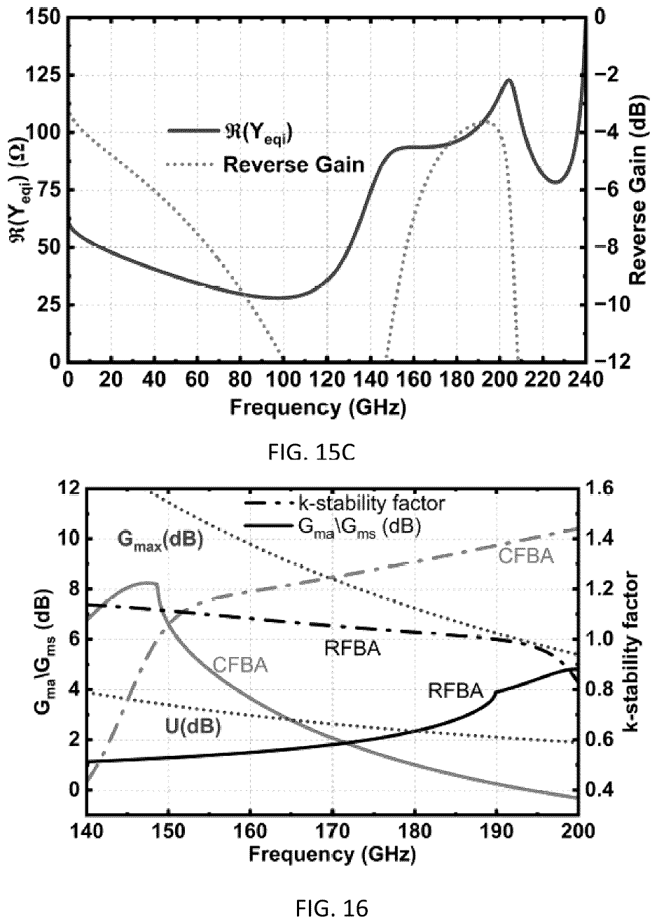

FIGS. 15A-15C respectively plot characteristic transmission line impedance, transmission line propagation factor and power gain for an example RFBA cells in accordance with FIG. 2. FIG. 15A shows characteristic impedance

$$( {Z}_{P}^{′} )$$

of

$${TL}_{P}^{′} ,$$

FIG. 15B snows propagation factor (e^{γ}), and FIG. 15C [symbol] (Y_{eqi}) in the reverse direction for an example 13.6—μm NMOS transistor in 45—nm SOI embedded with 50-Ω transmission lines (θ_{P}=57.8° &θ_{S}=65.4° at 175 GHz). Bias point: J=300 μA/μm, V_{GS}=V_{DS}=0.6 V.

$${L}_{P}^{′}$$

in the reverse direction has passbands 0-90 GHz and 155 GHz—205 GHz; however, it is shunt-loaded with resistors ( [symbol] (Y_{eqi})>0) at all frequencies (FIG. 15C), confirming the attenuative functionality of the RFBA cell in the reverse direction. This is because the positive feedback is only present in the forward direction, which generates negative resistance. Conversely, there is an absence of feedback in the reverse direction. This behavior is required for stability. The reverse gain is presented in FIG. 15C.

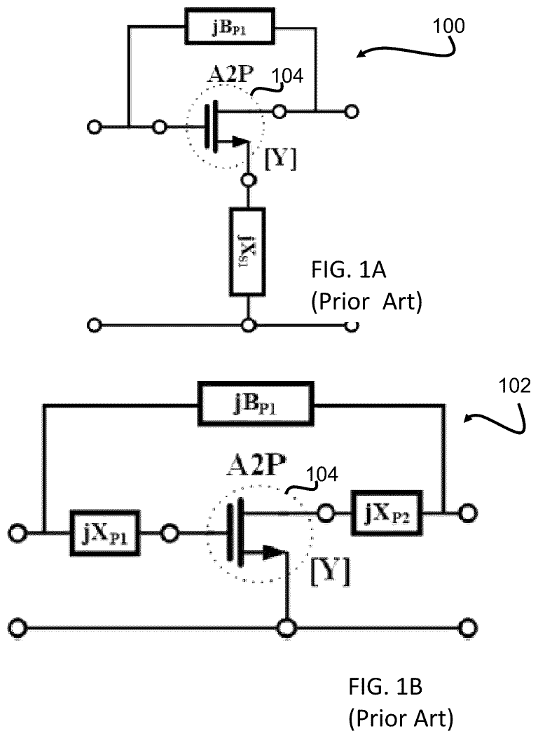

### Cascade of FIG. 2 RFBA and FIG. 1 CFBA

A cascaded amplifier of a preferred embodiment includes cascading two single-peak Gₘₐₓ-cores (single CFBA core and a single RFBA core) tuned at two different frequencies. The arrangement can provide high-gain and wideband response simultaneously.

FIG. 16 shows Gₘₐ \Gₘₛ and stability factor of a cascaded CFBA and RFBA amplifier of a preferred embodiment for an example embodiment embedded 13.6—μm NMOS transistor in 45—nm CMOS SOI (L_{g}=40 nm). Bias point: J=300 μA/μm, V_{GS}=V_{DS}=0.6 V Gₘₐ \Gₘₛ of a 13.6—μm NMOS transistor embedded in both CFBA and RFBA structures is plotted in FIG. 16. CFBA has a peak Gₘₐ achieving 8 dB at 150 GHz (ƒ₁) and is unconditionally stable above that, while the RFBA obtains its Gₘₐ peak with 4 dB gain at 190 GHz (ƒ₂) and is unconditionally stable below it. Therefore, an unconditionally stable amplifier with flat S₂₁ between ƒ₁ and ƒ₂ can be realized by cascading both structures. To compensate for the lower Gₘₐ of RFBA at ƒ₂ compared to that of CFBA at ƒ₁, multiple cells of FIG. 2 RFBAs can be cascaded, which gives a degree of freedom to the designer to tune for the best performance to match the requirements of a specific application.

### Circuit Design

Two preferred G-band amplifiers were designed and implemented in a 45—nm CMOS SOI process with eight metal layers and a traprich substrate. The design employs thin-oxide floating-body nMOS FETs with a 40—nm channel length. The transistor layout was selected to minimize interconnect parasitics. Double-side contacts and a relaxed pitch are incorporated in the gates to minimize resistance. Considering the device power consumption and Gₘₐ at G-band, the design uses the transistor size of 13.6 μm (16×850 nm) for all amp-cells, which has an fmax of 273 GHz when referenced to the fourth metal layer (C1). The top 4.1—μm-thick aluminum layer (LD) is employed to implement TLₛ, and all passive networks above the fourth metal layer (UA-LD) including RF pads are simulated using 3-D electromagnetic simulator.

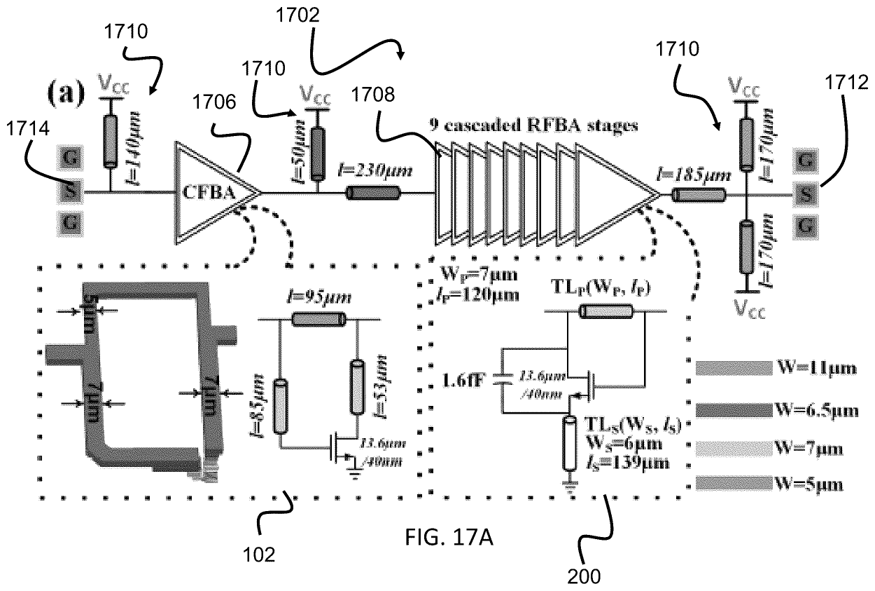

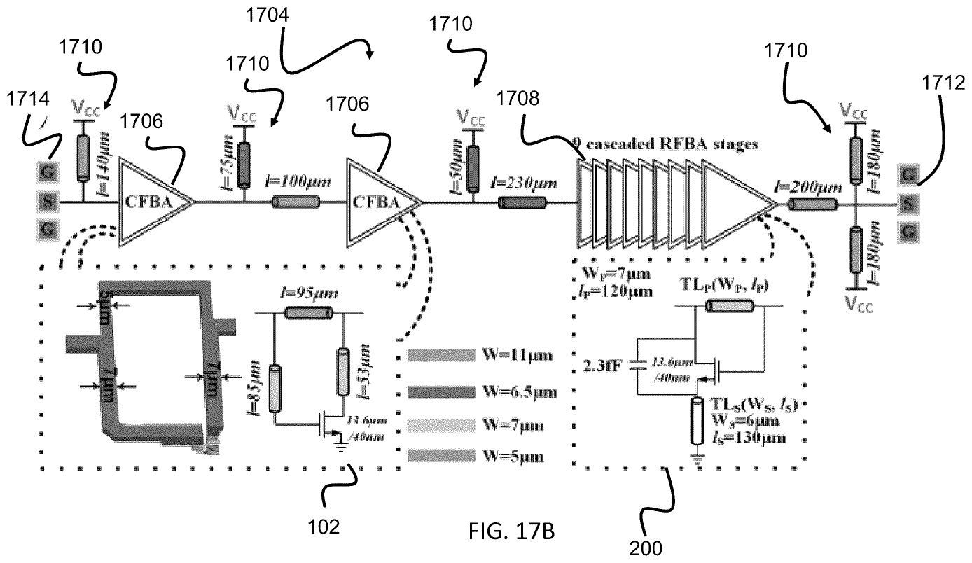

FIGS. 17A and 17B show two cascaded amplifiers 1702 and 1704 according to preferred embodiments. Amp-A (FIG. 17A) consists of 10 cascaded stages, including one CFBA 1706 constructed according to the CFBA 102 of FIG. 1B and a cascade 1708 of nine RFBA cells constructed according to the RFBA 200 of FIG. 2. Combining cascading with the reverse amplifier stages 1708 can lead to lower DC power consumption and smaller chip size compared to prior cascaded architectures. There are no matching networks between the cascade 1708 of the RFBA cells. Matching networks 1710 are provided to bias the CFBA 1706, and to match an impedance of a connected load at an output port 1712 of the amplifiers 1702 and 1704 and to match the impedance of a source at an input port 1714 of the amplifiers 1702 and 1704. The matching networks (MNs) bias the amplifier and balance V_{DD} across the chip. ISMNs are only included in between CFBA and first RFBA cell, as well as in between cascaded CFBA stages in the amplifier 1704 that includes multiple CFBA stages 1706. The transistors in Amp-A are biased at J=272 μA/μm, V_{GS}=V_{DS}=0.58 V. Amp-B (FIG. 17B) has 11-cascaded stages, including two CFBA and nine RFBA cells with the bias point of J=235 μA/μm, V_{GS}=V_{DS}=0.55 V. The bias points are chosen based on the gain requirement while minimizing power consumption. Post-layout simulated Gₘₐ of both CFBA and RFBA cells are plotted in FIGS. 4 and 16. A design goal is to obtain above 12 dB gain with equal 3-dB BW exceeding 35 GHz for both variants.

### RFBA Cells

Two different types of RFBA cells are employed in the amplifiers 1702 and 1704 of FIGS. 17A and 17B. In Amp-A 1702 in FIG. 17A, the RFBA cell 200 is optimized for maximum BW via longer TLₛ and lower C_{ds,ext}, while Amp-B 1704 aims for higher gain by including larger C_{ds, ext} (FIG. 4) in the RFBA cell 200 and an extra CFBA cell 1706. A longer TLₛ moves the coordinate of the amp-cell to the right in the gain plane, resulting in lower gain and broader BW. Thus, the length of TLₛ in Amp-A 1702 is higher than that in Amp-B 1704 to achieve a flatter gain.

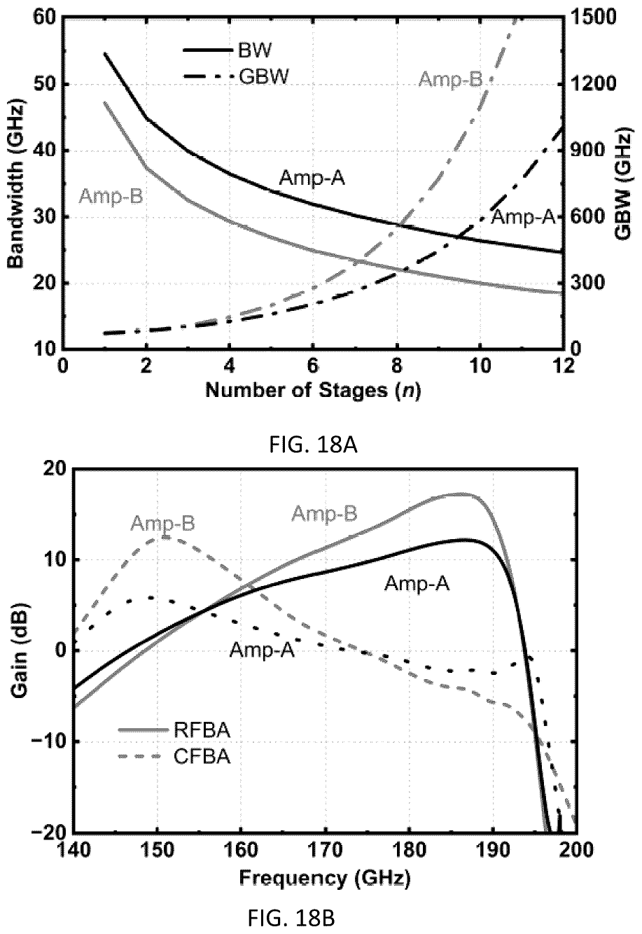

FIG. 18A depicts the theoretical BW and gain bandwidth product (GBW) for the two variants of RFBA cells 200. FIG. 18B shows post-layout EM-simulated gain of RFBA and CFBA cells in Amp-A and Amp-B versus frequency. There are two main trade-offs between gain and BW to consider. First, in cell design, the selection of design parameters (TLₚ, TL_{S}, and C_{ds, ext}) leads to either broader BW (Amp-A) or higher gain and GBW (Amp-B) as described in the previous paragraph by adjusting the TL lengths, pre-embedded capacitance and the number of CFBA cells used. Having more cascaded cells tends to decrease bandwidth despite higher gain. The example embodiments of FIGS. 17A and 17B used nine cascaded RFBA cells to provide a minimum gain of 11 dB is achieved. No matching network is included or needed between the RFBA cells since their input and output impedances are very close to the conjugate matching impedances. An output matching network including an RF output pad can terminate the RFBA cells to the required Y_(L,IT). A summary of post-layout simulation results follows:
i. The coordinates of the Amp-A and Amp-B in the gain plane are (0.47, 0.28) and (0.37, 0.29) at 175 GHz.
ii. The passband of

$${TL}_{P}^{′}$$

### is 46 GSz<ƒ<194.5 GHz.

iii. [symbol] (Y_{eqi}) remains negative (amplification range) in 146.8 GHz <ƒ<194.2 GHz. The amplification range of the RFBA should also cover the CFBA operation band, otherwise RFBA would be attenuative when cascaded with a CFBA cell.
iv. The phase of propagation factor reaches 0.5 η at 174 GHz.
v. The peak negative resistance of [symbol] (Y_{eqi}) is—280Ω (Amp-A) and—220Ω(Amp-B) at 178 GHz.
vi. G_{IT} is 1.3 dB (Amp-A) and 1.7 dB (Amp-B) at 175 GHz and only 0.2 dB less than Gₘₐ, which justifies the exclusion of MNs in between the RFBA cells.
vii. 3-dB BW for nine cascaded RFBA cells is 27.5 GHz for Amp-A (162.3-189.8 GHz) and 21 GHz for Amp-B (167.6-188.6 GHz).
viii. The NF of cascaded cells (FIG. 6C) is 9.3-dB (Amp-A) and 8.8-dB (Amp-B) at 175 GHz.

### CFBA Cell(s)

The CFBA cell is designed and embedded to boost the gain at the lower-end of the amplification band (FIG. 16), and hence extend the BW. The decision regarding the number of CFBA cells to cascade in the design relies only on the criteria of flattening the gain response achieved from RFBA cells. Therefore, Amp-A 1702 employs a single CFBA cell 1706, whereas two cells 1706 of CFBAs are utilized in Amp-B due to its RFBA cells' higher gain. CFBA cells 1706 are conjugately matched to RFBAs 1708 and optimized to flatten S₂₁. RF input and output pads 1712 and 1714 are treated as part of IMN (input matching network) and OMN (output matching network). Unlike STAs and dual-peak Gₘₐₓ-core amplifiers, fabricated prototypes of the amplifiers 1702 and 1704 showed input and output matching over the entire amplification band.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A reversed feedback amplifier, comprising:
a MOSFET comprising a drain input terminal connected to an amplifier input port and a gate output terminal connected to an amplifier output port;
a passive shunt admittance between the amplifier input and output terminals;
a series passive impedance in series with a source common terminal of the MOSFET; and
a pre-embedding capacitive admittance between the drain input terminal and the source common terminal of the MOSFET, wherein the passive shunt admittance and series passive impedance is selected to provide max gain operation of the MOSFET, and the pre-embedding capacitive admittance is selected to be absorbed into drain-source parasitic capacitance of the MOSFET, and to compensate passive losses of the passive shunt admittance and the series passive impedance.

2. The reversed feedback amplifier of claim 1, wherein the passive shunt admittance and the series passive impedance comprise transmission lines.

3. The reversed feedback amplifier of claim 1, wherein the MOSFET is fabricated in a silicon-on-insulator material system.

4. The reversed feedback amplifier of claim 1, wherein the MOSFET comprises a thin-oxide floating-body MOSFET.

5. A cascaded amplifier comprising a reversed feedback amplifier of claim 1 tuned to a first frequency and a second feedback amplifier tuned to a second frequency that is different than the first frequency.

6. The cascaded amplifier of claim 5, wherein the reversed feedback amplifier is on an output side of the cascaded amplifier.

7. A cascaded amplifier, comprising:
a plurality of reversed feedback amplifier cells forming a cascaded set according to claim 1 cascaded on an output side of the cascaded amplifier; and
an input side amplifier cell providing its output to the cascaded set of reversed feedback amplifier cells, wherein the input side amplifier provides peak gain at a lower frequency than peak gain provided by the cascaded set.

8. The cascaded amplifier of claim 7, comprising no interstage matching networks between reversed feedback amplifiers in the cascaded set of reversed feedback amplifier cells.

9. The cascaded amplifier of claim 8, comprising input and output matching networks.

10. A reversed feedback amplifier, comprising:
a MOSFET connected in a reversed direction as an active two-port network;
a passive shunt admittance connected to the MOSFET;
series passive impedance connected to the MOSFET; and
a capacitive admittance connected to the MOSFET, wherein the passive shunt admittance and series passive impedance are selected to provide max gain operation of the MOSFET and the capacitive admittance is selected to be absorbed into drain-source parasitic capacitance of the MOSFET, and to compensate passive losses of the passive shunt admittance and the series passive impedance.

11. The reversed feedback amplifier of claim 10, wherein the passive shunt admittance and the series capacitive admittance respectively introduce negative and positive feedback to the amplifier.

12. The reversed feedback amplifier of claim 10, wherein the passive shunt admittance and the series passive impedance comprise transmission lines.

13. A cascaded amplifier, comprising at least two reversed feedback amplifiers of claim 10, wherein one of the at least two reversed feedback amplifiers is tuned to a first frequency and another of the at least two reversed feedback amplifier is tuned to a second frequency that is different than the first frequency.

14. The cascaded amplifier of claim 13, comprising no matching network between the at least two reversed feedback amplifiers.
